(19) United States
(12) Patent Application Publication
(10) Pub. No.: US 2024/0174512 A1
(43) Pub. Date: May 30, 2024

(54) MICRO ELECTRO MECHANICAL SYSTEM PROBE AND MANUFACTURING METHOD THEREOF

(71) Applicant: TAIWAN MASK CORPORATION, HSINCHU (TW)

(72) Inventors: SHANG-KUANG WU, HSINCHU (TW); YU-TSUNG FU, HSINCHU (TW); MING-WEI HUANG, HSINCHU (TW)

(21) Appl. No.: 17/994,471

(22) Filed: Nov. 28, 2022

(51) Int. Cl. B81C 1/00

(52) U.S. Cl. CPC B81C 1/00055; B81C 2201/0133; B81C 2201/0142; B81C 2201/0159

(57) ABSTRACT

A MEMS probe and manufacturing method thereof are provided. The method is mainly to form connected first-level, second-level, and third-level pin grooves on both sides of the silicon substrate through an etching process, followed by two electroplating processes to deposit nickel-cobalt-phosphorus alloy in the first-level pin groove to form the tip of the microprobe, and to deposit nickel-cobalt alloy in the second-level pin groove and the third-level pin to form the pin head and pin arm, thereby forming a three-level microprobe. A circuit substrate made of ceramic material is disposed with at least one window, the surface of the circuit substrate adjacent to the window is provided with a plurality of circuit pads, and the circuit substrate is abutted to the pin arm of the microprobe. The silicon substrate is then removed, to form a plurality of cantilever microprobes made of nickel-cobalt-phosphorus alloy and nickel-cobalt alloy on the circuit substrate.

### BACKGROUND OF THE INVENTION

### 1. Field of the Invention

The present invention relates generally to the field of micro electro mechanical system (MEMS) probes, and more particularly, to a MEMS probe made of nickel-cobalt-phosphorus alloy and nickel-cobalt alloy and the manufacturing method thereof.

### 2. The Prior Arts

As the semiconductor manufacturing technology is becoming more sophisticated and entering the nanometer (nano) era, the volume of the chip is shrinking, and the distance between the bonding pads is also shrinking naturally. Whether the probe equipment and the probe card can quickly and accurately contact the bonding pads becomes an important focus of wafer inspection technology.

The micro electro mechanical system (MEMS) probe card made by the MEMS process, more probes can be embedded in a unit area because the probes are small in size and can be arranged in high density, which meets the increasingly requirements for the smaller pad spacing, and has been widely used in high-frequency or wafer-level test operations. However, as the number of probes increases, it is also relatively time-consuming and labor-intensive to assemble the probe cards using a single-pin sequential alignment and assembly process, and the calibration and adjustment after assembly will also be time-consuming. Therefore, various improvements to the process have been proposed.

In addition, the MEMS probe formed by the MEMS process mainly uses nickel-cobalt alloy as the probe material, but the hardness of the nickel-cobalt alloy is low. Under continuous testing operations, the wear of the probe is faster and the life time is shorter. For this reason, the present invention is proposed to provide different manufacturing methods to produce probes with long service life, and at the same time, the assembly work can be simplified and shortened.

### SUMMARY OF THE INVENTION

A primary objective of the present invention is to provide a MEMS probe made of nickel-cobalt-phosphorus alloy and manufacturing method thereof; the MEMS probe has the advantages of high hardness and wear resistance, more convenient assembly, and production and lower cost.

To achieve the foregoing objective, the present invention provides the following technical solutions:

The present invention provides a manufacturing method of a MEMS probe, comprising the following steps: providing a silicon substrate having a first surface and a second surface opposite to each other, forming a plurality of first-level pin grooves by etching on the second surface; forming a plurality of second-level pin grooves by etching on the first surface of the silicon substrate, and each of the second-level pin grooves communicating with the corresponding first-level pin groove; forming a plurality of third-level pin grooves by etching on the first surface, and each of the third-level pin grooves communicating with the corresponding second-level pin groove; sputtering a conductive layer on inner surface of the first-level pin grooves, the second-level pin grooves, and the third-level pin grooves; with two electroplating processes, depositing nickel-cobalt-phosphorus alloy on the first-level pin groove to form the tip of the microprobe, and depositing nickel-cobalt alloy on inside of the second-level pin grooves and the third-level pin grooves to form pin head and pin arm of the microprobe; depositing at least one abutting metal layer on the surface of the microprobe; using a circuit substrate with a plurality of circuit pads and at least one window, the plurality of circuit pads being distributed close to the window, and the circuit substrate being bonded and fixed by the circuit pads and the abutting metal layer; removing the silicon substrate and the conductive layer to form micro electro mechanical system (MEMS) probes, wherein one end of the plurality of microprobes is fixed to the circuit substrate and other end extends to below the window.

In a preferred embodiment, after forming the first-level pin grooves on the silicon substrate, the silicon substrate is turned over 180 degrees so that the first-level pin grooves face downward and the first surface faces upward.

In a preferred embodiment, the silicon substrate is etched by a inductively coupled plasma (ICP) anisotropic etching process to form the first-level pin grooves, the second-level pin grooves, and the third-level pin grooves.

In a preferred embodiment, the conductive layer is implanted by metal sputtering, and the material of the conductive layer is at least one of titanium, titanium tungsten, and copper.

In a preferred embodiment, the composition of the electroplating solution used in the electroplating process at least includes: nickel sulfate, nickel chloride, cobalt sulfate, cobalt chloride, sodium phosphate, ethylenediaminetetraacetic acid, and tartaric acid potassium sodium.

In a preferred embodiment, the electroplating solution used in the electroplating process further includes 1-3% ethylenediaminetetraacetic acid.

In a preferred embodiment, the lateral length of the abutting metal layer is 10-15% of the lateral length of upper surface of the microprobe.

In a preferred embodiment, the circuit substrate is made of ceramic material.

The present invention also provides a micro electro mechanical system (MEMS) probe, comprising: a plurality of microprobes and a circuit substrate, each of the microprobes comprising a pin tip, a pin head, and a pin arm, the pin tip is made of nickel-cobalt-phosphorus alloy, the pin head and the pin arm are made of nickel-cobalt alloy; the circuit substrate is provided with a plurality of circuit pads and at least one window, one end of the pin arm is connected to the circuit pad, and the other end of the pin arm extends to below the window.

In a preferred embodiment, in the nickel-cobalt-phosphorus alloy of the pin tip, the percentage by weight of nickel is 50-56%, the percentage by weight of cobalt is 41-47%, and the percentage by weight of phosphorus is 1-4%.

Compared with the prior art, the present invention forms the MEMS probe with composite material, because the tip is made of nickel-cobalt-phosphorus alloy, which has a hardness better than that of the conventional nickel-cobalt alloy probe, so that the contact effect is better, and is more wear-resistant to prolong the service life. In addition, the present invention can densely fix a large number of microprobes on the circuit substrate simultaneously, thereby forming a MEMS probe structure, which saves the trouble of traditional individual pin planting to achieve convenience and precision, and reduces the assembly cost. Therefore, the present invention makes the product more competitive in the market under the condition of increasing the service life and reducing the manufacturing cost.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a schematic side view of a MEMS probe according to an embodiment of the present invention;

FIG. 2 is a flowchart of a manufacturing method of a MEMS probe according to an embodiment of the present invention; and

FIGS. 3A-3J are schematic views of the flowchart of a manufacturing method of a MEMS probe according to an embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

The technical solutions of the present invention will be described clearly and completely below in conjunction with the specific embodiments and the accompanying drawings. It should be noted that when an element is referred to as being “mounted or fixed to” another element, it means that the element can be directly on the other element or an intervening element may also be present. When an element is referred to as being “connected” to another element, it means that the element can be directly connected to the other element or intervening elements may also be present. In the illustrated embodiment, the directions indicated up, down, left, right, front and back, etc. are relative, and are used to explain that the structures and movements of the various components in this case are relative. These representations are appropriate when the components are in the positions shown in the figures. However, if the description of the positions of elements changes, it is believed that these representations will change accordingly.

Unless otherwise defined, all technical and scientific terms used herein have the same meaning as commonly understood by one of ordinary skill in the art of the present invention. The terminology used herein is for the purpose of describing particular embodiments only and is not intended to limit the present invention. As used herein, the term “and/or” includes any and all combinations of one or more of the associated listed items.

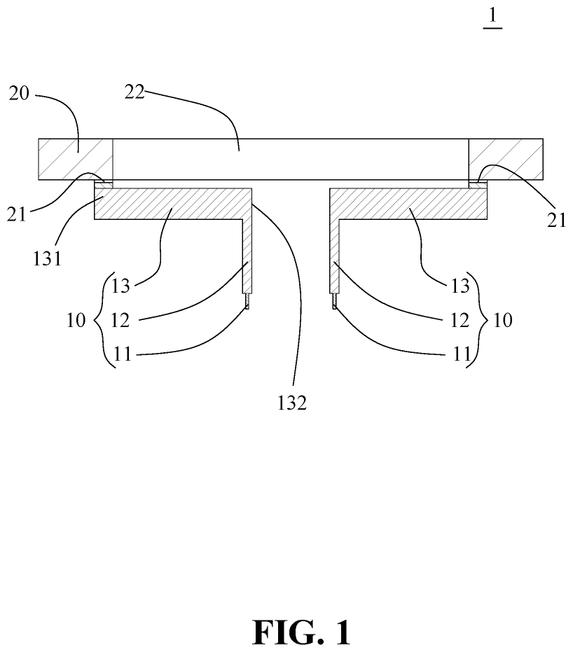

FIG. 1 is a schematic side view of a MEMS probe according to an embodiment of the present invention. As shown in FIG. 1, the MEMS probe 1 includes a plurality of microprobes 10 and a circuit substrate 20, and the microprobe 10 is a three-level probe structure formed by a pin tip 11, a pin head 12, and a pin arm 13; wherein the pin tip 11 is made of nickel-cobalt-phosphorus alloy, the pin head 12 and the pin arm 13 are mainly made of nickel-cobalt alloy; the pin arm 13 is elongated and has a fixed end 131 and a free end 132 that can be shifted; the pin arm 13 is electrically connected to the circuit substrate 20 by the fixed end 131, the pin head 12 is located at the free end 132 of the pin arm 13 and extends downward, and the pin tip 11 is located at the pin head 12 and extends downward, as such, a cantilevered MEMS probe 1 is formed.

The circuit substrate 20 is made of ceramic material, and can be made of a single-layer or multi-layer ceramic board. The circuit substrate 20 is provided with a plurality of electrical circuits and a plurality of circuit pads 21. The electrical circuits are distributed on the surface of the circuit substrate 20, or distributed in a multi-layer structure as three-dimensional circuits. As this is a known structure, the description will not be repeated here. The circuit pads 21 are distributed on the surface of the circuit substrate 20 for electrical connection with the microprobe 10. Each of the circuit pads 21 is connected to a corresponding electrical circuit, and a plurality of electrical circuits can be distributed in a fan layout to increase the spacing between the end contacts. In the present embodiment, in order to make the microprobe 10 possess the shift characteristic of the cantilever probe, the circuit substrate 20 has at least one penetrating window 22, and the plurality of circuit pads 21 is distributed on the surface of the circuit substrate 20 at the area immediately adjacent to the window 22. In the MEMS probe 1 of the present invention, the circuit substrate 20 is made of ceramic material, which has high hardness. The ceramic material is not easily deformed due to stress or high temperature conditions when the microprobes 10 contacts the electronic components to be tested on the wafer. Also, because the ceramic material has insulating properties, there will be no leakage current effect between adjacent microprobes 10 even though the microprobes 10 are numerous and arranged in high density, thereby providing high-quality testing operations. Moreover, the pin tip 11 made of nickel-cobalt-phosphorus alloy has high hardness, wear resistance, and resistance to damage, which will increase the service life and have great cost benefits.

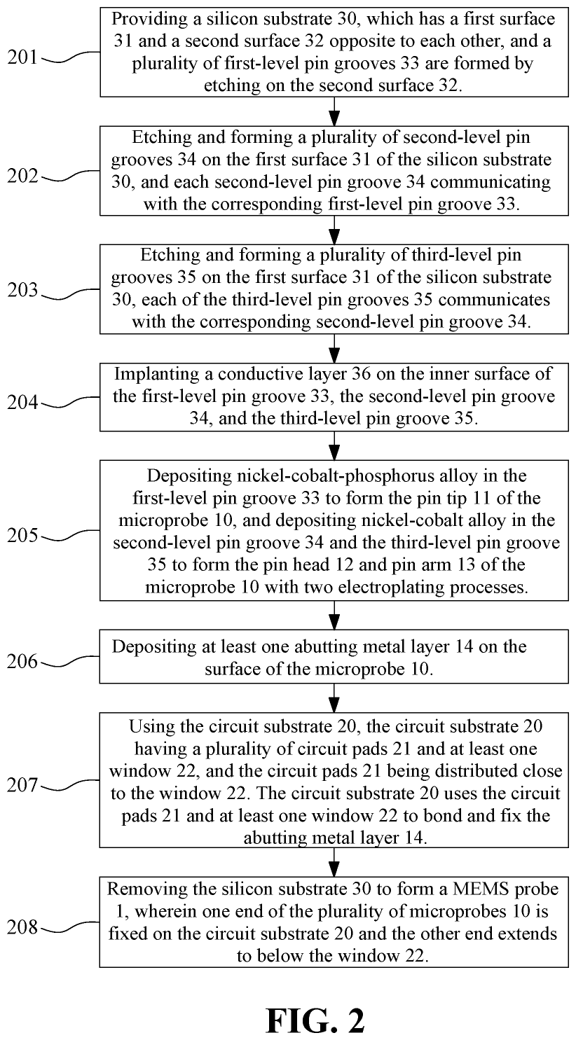

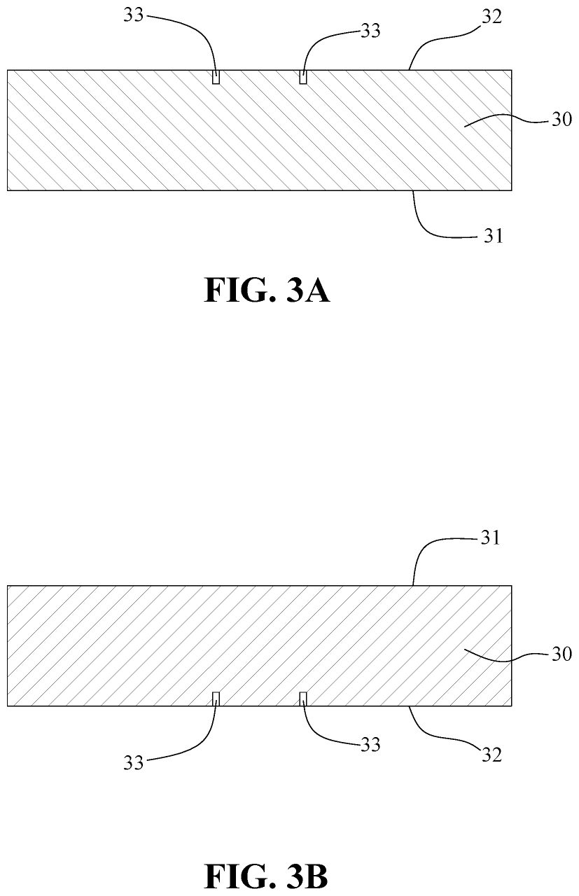

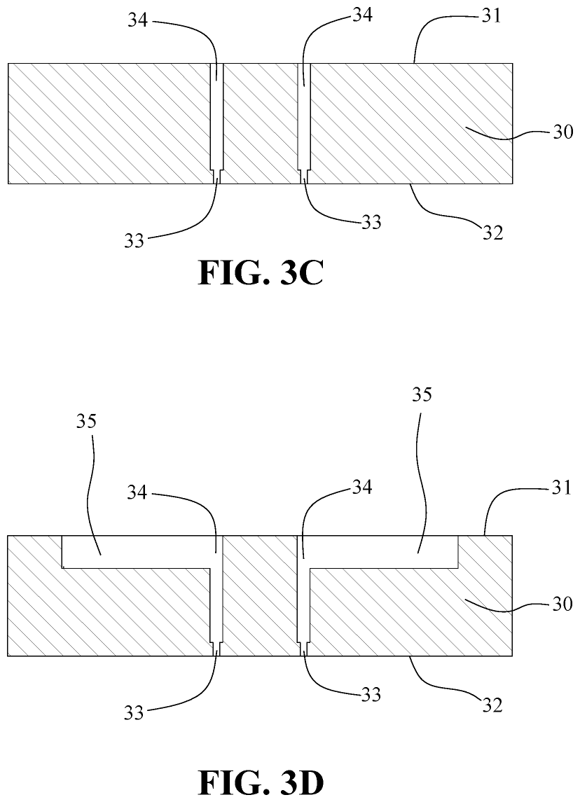

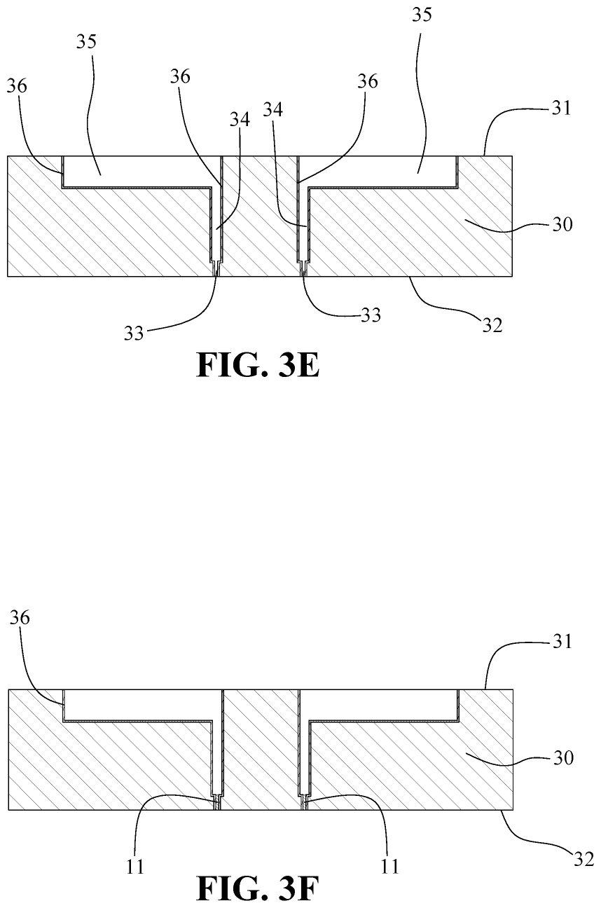

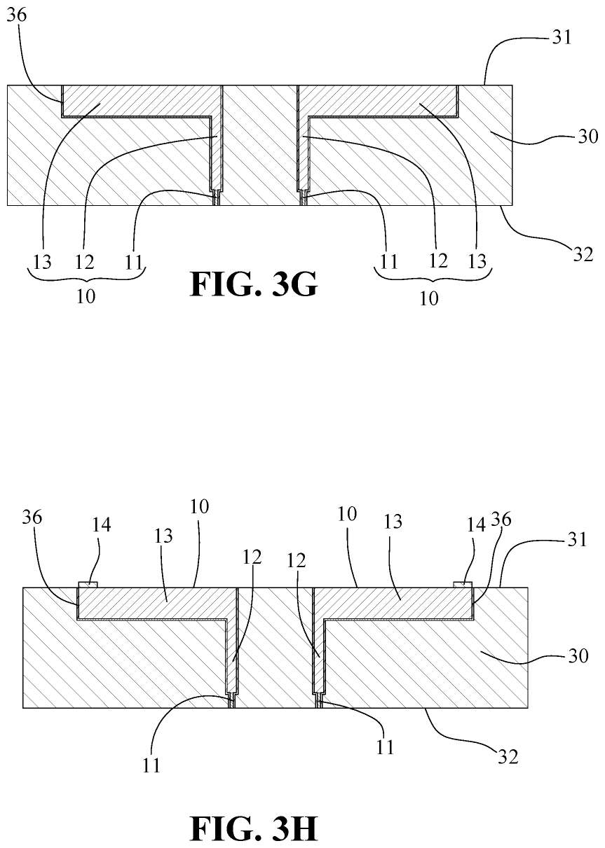

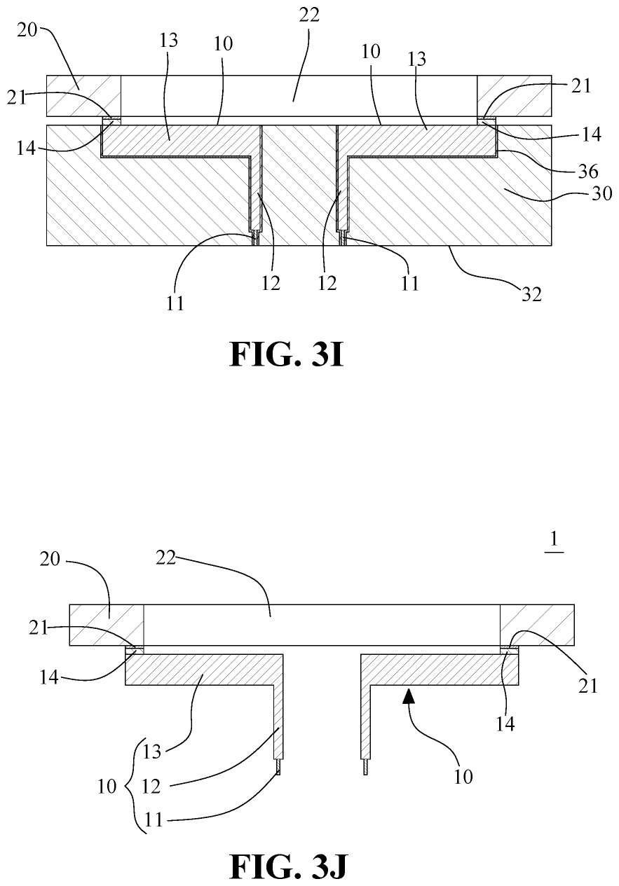

Refer to FIG. 2, which is a flow chart of the manufacturing method of a MEMS probe according to an embodiment of the present invention, in combination with FIG. 3A to FIG. 3J, the manufacturing method comprises the following steps:

Step 201: Providing a silicon substrate 30, which has a first surface 31 and a second surface 32 opposite to each other, and a plurality of first-level pin grooves 33 are formed by etching on the second surface 32. As shown in FIG. 3A, in the present embodiment, the silicon substrate 30 can be a silicon wafer. First, the second surface 32 of the silicon substrate 30 (that is, the back side of the silicon wafer) faces upward, and the silicon substrate 30 is etched by lithography to form the first-level pin groove 33 on the second surface 32, which further includes the following steps: forming a photoresist pattern on the second surface 32, and then using inductively coupled plasma (ICP) anisotropic etching to expose the second surface 32 of the photoresist pattern to form the first-level pin groove 33 of a required depth, and then removing the photoresist pattern. The ICP etching rate is 1.5 um-2.5 um/min, and the depth of the first-level pin groove can be controlled by etching time 33. In the present embodiment, the depth of the first-level pin groove 33 is about 45-55 μm, and the time for ICP to perform anisotropic etching is about 20-35 minutes. As shown in FIG. 3B, after completing, the silicon substrate 30 is flipped over by 180 degrees after so that the first-level pin grooves 33 face downward, and at this time the first surface 31 (i.e., the front side of the silicon wafer) faces upward.

Step 202: Etching and forming a plurality of second-level pin grooves 34 on the first surface 31 of the silicon substrate 30, and each second-level pin groove 34 communicating with the corresponding first-level pin groove 33. As shown in FIG. 3C, the first surface 31 is facing upwards, and the second-level pin groove 34 is formed by lithography etching, which includes: forming a photoresist pattern on the first surface 31, and then using inductively coupled plasma (ICP) anisotropic etching to expose the first surface 31 of the photoresist pattern to form the second-level pin groove 34 with a required depth, so that the second-level pin groove 34 communicates with, i.e., is connected to, the first-level pin groove 33, and the lateral width of the second-level pin groove 34 is larger than the lateral width of the first-level pin groove 33. In the present embodiment, the depth of the second-level pin groove 34 is about 235-245 μm, and the time for the ICP to perform anisotropic etching is about 120-210 minutes.

Step 203: Etching and forming a plurality of third-level pin grooves 35 on the first surface 31 of the silicon substrate 30, each of the third-level pin grooves 35 communicates with the corresponding second-level pin groove 34. As shown in FIG. 3D, the third-level pin grooves 35 are etched at different positions on the first surface 31 to communicate with the second-level pin grooves 34. In the present embodiment, the third-level pin groove 35 with a required depth is formed the first surface 31 by the inductively coupled plasma (ICP) anisotropic etching, the depth of the third-level pin groove 35 is about 95-105 μm, and the time for ICP to perform anisotropic etching is about 40-70 minutes.

Step 204: Implanting a conductive layer 36 on the inner surface of the first-level pin groove 33, the second-level pin groove 34, and the third-level pin groove 35. As shown in FIG. 3E, in the present embodiment, the conductive layer 36 is implanted by metal sputtering on the inner surfaces of the first-level pin grooves 33, the second-level pin grooves 34, and the third-level pin grooves 35. The metal of the conductive layer may be at least one of titanium (Ti), titanium tungsten (Tiw), and copper (Cu). The function of the conductive layer 36 is to provide a conductive interface required in the subsequent electroplating process.

Step 205: Depositing nickel-cobalt-phosphorus alloy in the first-level pin groove 33 to form the pin tip 11 of the microprobe 10, and depositing nickel-cobalt alloy in the second-level pin groove 34 and the third-level pin groove 35 to form the pin head 12 and pin arm 13 of the microprobe 10 with two electroplating processes. As shown in FIG. 3F, the pin tip 11 is first deposited. The materials and conditions of the electroplating process used in the present embodiment are as follows: using an electroplating solution including nickel sulfate, nickel chloride, cobalt sulfate, cobalt chloride, sodium phosphate, ethylenediaminetetraacetic acid (EDTA), potassium sodium tartrate, setting process temperature to 50-70 degrees, and controlling the process time precisely. When the nickel-cobalt-phosphorus alloy is completely deposited in the first-level pin groove 33, the electroplating process is stopped. The electroplating process is mainly to separate nickel from nickel sulfate and nickel chloride, separate cobalt from cobalt sulfate and cobalt chloride, separate phosphorus from sodium phosphate, and the separated nickel, cobalt and phosphorus form a nickel-cobalt-phosphorus alloy. Wherein, the ethylenediaminetetraacetic acid (EDTA) is an additive, with a weight percentage of 1-3%, which is used in the electroplating process to avoid holes in the pin tip 11 and improve the electroplating yield and the performance of the microprobe 10. In this electroplating process, there may be a small amount of nickel-cobalt-phosphorus alloy attached to the surface of the second-level pin groove 34 and the third-level pin groove 35, and the amount is so small that is negligible. As shown in FIG. 3G, the pin head 12 and the pin arm 13 are formed by depositing nickel-cobalt alloy in the second-level pin groove 34 and the third-level pin groove 35 by replacing the electroplating solution for the second electroplating process. If the height of the microprobe 10 formed during the electroplating process protrudes from the first surface 31 and the second surface 32, the microprobe 10 protruding from the first surface 31 and the second surface 32 can be removed by grinding. The microprobe 10 is a three-level structure including the pin tip 11, the pin head 12, and the pin arm 13.

Step 206: depositing at least one abutting metal layer 14 on the surface of the microprobe 10. As shown in FIG. 3H, the abutting metal layer 14 is formed on a partial area of the upper surface of the pin arm 13 of the microprobe 10 by lithography, and is located is far away from the pin head 12. The abutting metal layer 14 is used to abut the circuit substrate 20, the lateral length of the abutting metal layer 14 accounts for 10-15% of the lateral length of the upper surface of the pin arm 13 of the microprobe 10.

Step 207: using the circuit substrate 20, the circuit substrate 20 having a plurality of circuit pads 21 and at least one window 22, and the circuit pads 21 being distributed close to the window 22. The circuit substrate 20 uses the circuit pads 21 and at least one window 22 to bond and fix the abutting metal layer 14. As shown in FIG. 3I, in the present embodiment, the circuit substrate 20 is made of ceramic material and uses a semiconductor process to form electrical circuits (not shown) and a plurality of circuit pads 21, and the distribution, positions and the sizes of the plurality of circuit pads 21 are precisely controlled. The circuit substrate 20 is placed on the microprobe 10 from top downward, so that each of the circuit pads 21 is docked on the abutting metal layer 14 and then cured by heating or other methods to firmly combine the two, and a plurality of microprobes 10 are fixed on the circuit substrate 20.

Step 208: removing the silicon substrate 30 to form a MEMS probe 1, wherein one end of the plurality of microprobes 10 is fixed on the circuit substrate 20 and the other end extends to below the window 22. As shown in FIG. 3J, in the present embodiment, the silicon substrate 30 and the conductive layer 36 can be removed by means of wet etching chemical reaction. The nickel-cobalt alloy in the groove 34 and the third-level pin groove 35 forms the pin tip 11, the pin head 12, and the pin arm 13 of the microprobe 10, so that the plurality of microprobes 10 are fixed on the circuit substrate 20 and extend to below the window 22 to form a cantilevered MEMS probe 1.

The composition of the pin tip 11 of the MEMS probe 1 completed by the aforementioned manufacturing method is as shown in the table below:

| Element | Weight % | Weight % Sigma | Atomic % |
|---|---|---|---|
| P | 1.65 | 0.08 | 3.09 |
| Co | 44.80 | 0.36 | 44.05 |
| Ni | 53.55 | 0.37 | 52.86 |
| Total | 100.00 | | 100.00 |

Measured by the Vickers hardness tester, the hardness is greater than 600 Hv, up to 627 Hv.

Utilizing the characteristics of high hardness of the pin tip 11, the microprobe 10 of the present invention has the advantages of wear resistance and long service life. The pin tip 11 of the present invention is not limited to the composition of the aforementioned embodiments. In other embodiments, the weight percentage of nickel is 50-56%, the weight percentage of cobalt is 41-47%, and the weight percentage of phosphorus is 1-4%.

In summary, the MEMS probe made of composite materials in the present invention utilizes a precise process through division of labor. For example, the silicon substrate is formed with a plurality of microprobes made of nickel-cobalt-phosphorus alloy and nickel-cobalt alloy by its manufacturing method. The circuit substrate is formed with a precise circuit by semiconductor process, and then the silicon substrate is removed after the two are docked, so that a large number of the microprobes can be densely fixed on the circuit substrate at one time, which is fast, convenient and accurate. Moreover, the present invention obtains a nickel-cobalt-phosphorus alloy tip with good hardness, which has the advantages of wear resistance and long service life, and thus meets the requirements of the MEMS probes nowadays.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A manufacturing method of micro electro mechanical system (MEMS) probe, comprising the steps of:
a. providing a silicon substrate having a first surface and a second surface opposite to each other, forming a plurality of first-level pin grooves by etching on the second surface;
b. forming a plurality of second-level pin grooves by etching on the first surface of the silicon substrate, and each of the second-level pin grooves communicating with the corresponding first-level pin groove;
c. forming a plurality of third-level pin grooves by etching on the first surface, and each of the third-level pin grooves communicating with the corresponding second-level pin groove;
d. sputtering a conductive layer on inner surface of the first-level pin grooves, the second-level pin grooves, and the third-level pin grooves;
e. using two electroplating processes to deposit nickel-cobalt-phosphorus alloy on the first-level pin groove to form the tip of the microprobe, and deposit nickel-cobalt alloy on inside of the second-level pin grooves and the third-level pin grooves to form pin head and pin arm of the microprobe;
f. depositing at least one abutting metal layer on the surface of the microprobe;
g. using a circuit substrate with a plurality of circuit pads and at least one window, the plurality of circuit pads being distributed close to the window, and the circuit substrate being bonded and fixed by the circuit pads and the abutting metal layer; and
h. removing the silicon substrate and the conductive layer to form MEMS probes, wherein one end of the plurality of microprobes is fixed to the circuit substrate and other end extends to below the window.

2. The manufacturing method of MEMS probe according to claim 1, wherein in step a., after forming the first-level pin grooves on the silicon substrate, the silicon substrate is turned over 180 degrees so that the first-level pin grooves face downward and the first surface faces upward.

3. The manufacturing method of MEMS probe according to claim 1, wherein in steps a., b., and c., the silicon substrate is etched by a inductively coupled plasma (ICP) anisotropic etching process to form the first-level pin grooves, the second-level pin grooves, and the third-level pin grooves.

4. The manufacturing method of MEMS probe according to claim 1, wherein in step d., the conductive layer is implanted by metal sputtering, and the material of the conductive layer is at least one of titanium, titanium tungsten, and copper.

5. The manufacturing method of MEMS probe according to claim 1, wherein in step e., the composition of the electroplating solution used in the electroplating process at least includes: nickel sulfate, nickel chloride, cobalt sulfate, cobalt chloride, sodium phosphate, ethylenediaminetetraacetic acid, and tartaric acid potassium sodium.

6. The manufacturing method of MEMS probe according to claim 5, wherein in step e., the electroplating solution used in the electroplating process further includes 1-3% ethylenediaminetetraacetic acid.

7. The manufacturing method of MEMS probe according to claim 1, wherein the lateral length of the abutting metal layer is 10-15% of the lateral length of upper surface of the microprobe.

8. The manufacturing method of MEMS probe according to claim 1, wherein in step g., the circuit substrate is made of ceramic material.

9. A micro electro mechanical system (MEMS) probe, comprising:
a plurality of microprobes and a circuit substrate, each of the microprobes comprising a pin tip, a pin head, and a pin arm; wherein the pin tip being made of nickel-cobalt-phosphorus alloy, the pin head and the pin arm being made of nickel-cobalt alloy; the circuit substrate being provided with a plurality of circuit pads and at least one window, one end of the pin arm being connected to the circuit pad, and the other end of the pin arm extending to below the window.

10. The MEMS probe according to claim 9, wherein in the nickel-cobalt-phosphorus alloy of the pin tip, the percentage by weight of nickel is 50-56%, the percentage by weight of cobalt is 41-47%, and the percentage by weight of phosphorus is 1-4%.
